(19) United States
(12) Patent Application Publication
(10) Pub. No.: US 2022/0376676 A1
(43) Pub. Date: Nov. 24, 2022

(54) HIGH-ISOLATION AND ANTI-GLUE-INVASION SAW DUPLEXER

(71) Applicant: CHENGDU PINNACLE MICROWAVE CO., LTD., Chengdu (CN)

(72) Inventors: Yuandan DONG, Chengdu (CN); Hao XUE, Chengdu (CN); Mengjuan ZHAO, Chengdu (CN); Tao YANG, Chengdu (CN); Zenghong MA, Chengdu (CN)

(21) Appl. No.: 17/852,653

(22) Filed: Jun. 29, 2022

Related U.S. Application Data
(63) Continuation of application No. PCT/CN2021/133445, filed on Nov. 26, 2021.

(30) Foreign Application Priority Data
May 18, 2021 (CN) 202110538672.8

(51) Int. Cl. H03H 9/72; H03H 9/25; H03H 9/64

(52) U.S. Cl. CPC H03H 9/725; H03H 9/25; H03H 9/6483

(57) ABSTRACT

A high-isolation and anti-glue-invasion Surface Acoustic Wave (SAW) duplexer includes a transmitting filter and a receiving filter. The isolation of the duplexer is improved by adjusting the positions of parallel resonance arms of the receiving filter and optimizing the distances between a grounding metal wiring of a Double Mode Structure (DMS) filter in the receiving filter and other grounding metal wirings and a distance between the grounding metal wiring of the DMS filter in the receiving filter and a signal metal wiring, and the grounding metal wiring is further arranged to surround the series resonance arms and the parallel resonance arms, so as to fill blank positions between the resonance arms and the edge of a package.

### CROSS REFERENCE TO RELATED APPLICATIONS

This patent application is a continuation of International Application No. PCT/CN2021/133445, filed on Nov. 26, 2021, which claims priority to Chinese Patent Application No. 202110538672.8 filed on May 18, 2021. Both of the aforementioned applications are hereby incorporated by reference in their entireties.

### TECHNICAL FIELD

The present disclosure relates to the technical field of antenna, and in particular, to a high-isolation and anti-glue-invasion Surface Acoustic Wave (SAW) duplexer.

### BACKGROUND

An existing duplexer is usually difficult to meet the requirement for high isolation on the current market, especially for a technical level that the requirement for the isolation is better than 60 dB. Constructing a branch circuit with equal amplitude and reversed phase by using a compensation circuit is not beneficial to a further miniaturization process of the duplexer, thus affecting the integration of a transceiver module of a mobile phone. In addition, according to the filtering performance and the power tolerance of the existing duplexer, the layout of a transmitting filter is often close to the edge of a package, and the performance of a resonance arm is prone to be influenced by glue entering the duplexer, which is a problem that needs to be solved in a design of an SAW duplexer.

### SUMMARY

In order to solve the above-mentioned problem in the prior art, the present disclosure provides as SAW duplexer which has high isolation characteristics and prevents an influence of glue invasion.

To achieve the above-mentioned object, the present disclosure provides the following solutions.

A first high-isolation SAW duplexer includes an antenna terminal, a transmitting terminal, a receiving terminal, a substrate, and a duplexer chip arranged on the substrate. The duplexer chip includes a piezoelectric substrate, and a transmitting filter and a receiving filter constructed on a surface of the piezoelectric substrate. The transmitting filter is connected between the antenna terminal and the transmitting terminal. The receiving filter is connected between the antenna terminal and the receiving terminal. The receiving filter includes a series resonance arm S5, a series resonance arm S6, and a series resonance arm S7 sequentially connected in series between the antenna terminal and the receiving terminal. A Double Mode Structure (DMS) filter is connected between the series resonance arm S5 and one end of the series resonance arm S6. An other end of the series resonance arm S6 is connected to the series resonance arm S7 and one end of a parallel resonance arm P4. Grounding ends of the DMS filter are respectively connected to a first ground potential and a second ground potential. An other end of the parallel resonance arm P4 is connected to the first ground potential or the second ground potential.

The transmitting filter includes: a parallel resonance arm P1, a parallel resonance arm P2, and a parallel resonance arm P3. The transmitting filter further includes: a series resonance arm S1, a series resonance arm S2, a series resonance arm S3, and a series resonance arm S4 sequentially connected in series between the transmitting terminal and the antenna terminal. One end of the parallel resonance arm P1 is connected between the series resonance arm S1 and the series resonance arm S2. One end of the parallel resonance arm P2 is connected between the series resonance arm S2 and the series resonance arm S3. One end of the parallel resonance arm P3 is connected between the series resonance arm S3 and the series resonance arm S4. An other end of the parallel resonance arm P1, an other end of the parallel resonance arm P2, and an other end of the parallel resonance arm P3 are connected to a third ground potential.

In some embodiments, a first grounding end of the DMS filter is connected to the first ground potential through a first grounding metal wiring. A second grounding end of the DMS filter is connected to the second ground potential through a second grounding metal wiring. The second ground potential is connected with an inductor L1 at a metal layer of the substrate, and an inductance value of the inductor L1 is 0.2 nH. The first ground potential is not connected with an inductor at the metal layer of the substrate. The parallel resonance arm P4 is connected to the first ground potential through a third grounding metal wiring.

In some embodiments, the parallel resonance arm Pl, the other end of the parallel resonance arm P2, and the other end of the parallel resonance arm P3 are commonly connected to the third ground potential through grounding metal wirings. The third ground potential is connected to an inductor L2 at the metal layer of the substrate, and the inductance value of the inductor L2 is 0.1 nH.

A distance between the second grounding metal wiring of the DMS filter in the receiving filter and the grounding metal wiring of the parallel resonance arm in the transmitting filter is greater than 100 μm, and a distance between the second grounding metal wiring of the DMS filter and a signal metal wiring in the receiving filter is within the range of 30 to 50 μm.

In some embodiments, each of the series resonance arm S1, the series resonance arm S2, and the series resonance arm S4 includes three SAW resonators. Each of the series resonance arm S3, the parallel resonance arm P1, the parallel resonance arm P2, and the parallel resonance arm P3 includes two SAW resonators.

Each of the series resonance arm S5 and the parallel resonance arm P4 includes two SAW resonators.

In some embodiments, resonance frequencies fₛ of the series resonance arm S5 and the series resonance arm S6 are within a pass band range of the receiving filter. An anti-resonance frequency fₐ of the series resonance arm S7 is within a pass band range of the transmitting filter.

A second high-isolation SAW duplexer includes: an antenna terminal, a transmitting terminal, a receiving terminal, and a duplexer chip.

The duplexer chip includes: a transmitting filter and a receiving filter.

One end of the transmitting filter is connected to the antenna terminal. An other end of the transmitting filter is connected to the transmitting terminal. One end of the receiving filter is connected to the antenna terminal. An other end of the receiving filter is connected to the receiving terminal.

In some embodiments, the duplexer chip further includes a piezoelectric substrate.

Both the transmitting filter and the receiving filter are arranged on the piezoelectric substrate.

In some embodiments, the transmitting filter includes: a first series resonance arm, a second series resonance arm, a third series resonance arm, a fourth series resonance arm, a first parallel resonance arm, a second parallel resonance arm, and a third parallel resonance arm.

One end of the first series resonance arm is connected to the transmitting terminal. An other end of the first series resonance arm is connected to one end of the second series resonance arm. An other end of the second series resonance arm is connected to one end of the third series resonance arm. An other end of the third series resonance arm is connected to one end of the fourth series resonance arm. An other end of the fourth series resonance arm is connected to the antenna terminal. One end of the first parallel resonance arm is connected to a connection path between the first series resonance arm and the second series resonance arm. One end of the second parallel resonance arm is connected to a connection path between the second series resonance arm and the third series resonance arm. One end of the third parallel resonance arm is connected to a connection path between the third series resonance arm and the fourth series resonance arm. An other end of the first parallel resonance arm, an other end of the second parallel resonance arm, and an other end of the third parallel resonance arm are grounded.

In some embodiments, the receiving filter includes: a fifth series resonance arm, a sixth series resonance arm, a seventh series resonance arm, a fourth parallel resonance arm, and a DMS filter.

One end of the fifth series resonance arm is connected to the antenna terminal. An other end of the fifth series resonance arm is connected to one end of the DMS filter through a signal metal wiring. An other end of the DMS filter is connected to one end of the sixth series resonance arm through a signal metal wiring. An other end of the sixth series resonance arm is connected to one end of the seventh series resonance arm. An other end of the seventh series resonance arm is connected to the receiving terminal. A first grounding end of the DMS filter is connected to a first ground potential through a grounding metal wiring. A second grounding end of the DMS filter is connected to a second ground potential through a grounding metal wiring. One end of the fourth parallel resonance arm is connected to a connection path between the sixth series resonance arm and the seventh series resonance arm. An other end of the fourth parallel resonance arm is connected to a connection path between the first grounding end of the DMS filter and the first ground potential.

According to specific embodiments provided by the present disclosure, the present disclosure discloses the following technical effects.

According to the high-isolation SAW duplexer provided by the present disclosure, the isolation of the duplexer is improved by adjusting the positions of the parallel resonance arms of the receiving filter and optimizing the distance between the grounding metal wiring of the DMS filter in the receiving filter and other grounding metal wiring and the distance between the grounding metal wiring of the DMS filter in the receiving filter and the signal metal wiring, and the grounding metal wiring is arranged to surround the series resonance arms and the parallel resonance arms, so as to fill blank positions between the resonance arms and the edge of the package, which skillfully prevents glue from entering the duplexer to affect the performance of the filter, during the packaging of a duplexer without increasing the cost. The SAW duplexer of the present disclosure realizes the high isolation performance of less than -60 dB, which is beneficial to meeting higher requirements of the market for isolation and miniaturization of the SAW duplexer.

In addition, the present disclosure further provides a high-isolation and anti-glue-invasion SAW duplexer. The high-isolation SAW duplexer is the first or second high-isolation SAW duplexer provided above. In the high-isolation SAW duplexer, the grounding metal wiring for connecting the ground potential has an extension section, so as to surround the series resonance arms and the parallel resonance arms.

### BRIEF DESCRIPTION OF THE DRAWINGS

To describe the technical solutions in the embodiment of the present disclosure or in the prior art more clearly, the following briefly describes the accompanying drawings required for describing the embodiment. Apparently, the accompanying drawings in the following description are merely some embodiments of the present disclosure, and those of ordinary skills in the art may still derive other drawings from these accompanying drawings without creative efforts.

FIG. 1 illustrates a circuit diagram of a duplexer according to an embodiment of the present disclosure.

FIG. 2 illustrates a circuit diagram of a duplexer according to comparative example 1.

FIG. 3 illustrates a schematic top view of a structure of various metal layers of a substrate according to the embodiment of the present disclosure.

FIG. 4 illustrates an arrangement diagram of a transmitting filter and a receiving filter on a surface of a piezoelectric substrate according to the embodiment of the present disclosure.

FIG. 5 illustrates an arrangement diagram of the transmitting filter and the receiving filter on the surface of the piezoelectric substrate according to comparative example 1.

FIG. 6 illustrates an arrangement diagram of the transmitting filter and the receiving filter on the surface of the piezoelectric substrate according to comparative example 2.

FIG. 7 illustrates transmission curves of the transmitting filters according to the embodiment of the present disclosure, comparative example 1, and comparative example 2.

FIG. 8 illustrates transmission curves of the receiving filters according to the embodiment of the present disclosure, comparative example 1, and comparative example 2.

FIG. 9 illustrates isolation curves according to the embodiments of the present disclosure, comparative example 1, and comparative example 2.

FIG. 10 illustrates an arrangement diagram of the transmitting filter and the receiving filter on the surface of the piezoelectric substrate according to an anti-glue-invasion embodiment of the present disclosure.

### REFERENCE SIGNS IN THE DRAWINGS

1-antenna terminal; 2-transmitting terminal; 3-receiving terminal; 4-first ground potential; 5-second ground potential; 6-third ground potential; 7-fourth ground potential; 8-first grounding metal wiring; 9-second grounding metal wiring; 10-third grounding metal wiring; 11-fourth grounding metal wiring; 12-fifth grounding metal wiring; 13-first signal metal wiring; and 14-second signal metal wiring.

### DETAILED DESCRIPTION

Technical solutions in the embodiments of the present disclosure will be clearly and completely described below with reference to the drawings in the embodiments of the present disclosure. Apparently, the described embodiments are merely part rather than all of the embodiments of the present disclosure. On the basis of the embodiments of the present disclosure, all other embodiments obtained by those of ordinary skills in the art without creative work fall within the scope of protection of the present disclosure.

An object of the present disclosure is to provide an SAW duplexer with high isolation characteristics and capacity of preventing glue from entering, so as to solve the problems of the influence on the integration of a transceiver module of a mobile phone and the performance loss of the resonance arms caused by glue entering in the prior art.

In order to make the above-mentioned object, features, and advantages of the present disclosure more apparent and more comprehensible, the present disclosure is further described in detail below with reference to the drawings and specific implementation manners.

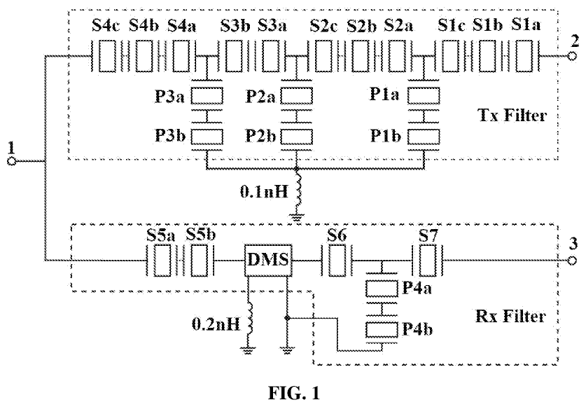

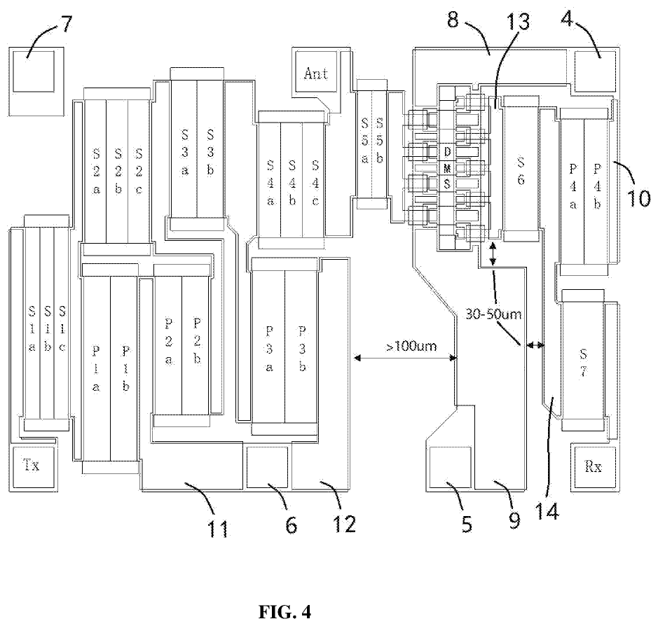

As shown in FIGS. 1 and 4, a high-isolation SAW duplexer provided by the embodiment includes a substrate and a duplexer chip arranged on the substrate. The duplexer chip includes a piezoelectric substrate, and a transmitting filter (Tx Filter) and a receiving filter (Rx Filter) constructed on a surface of the piezoelectric substrate. The transmitting filter is connected between an antenna terminal 1 and a transmitting terminal 2. The receiving filter is connected between the antenna terminal 1 and a receiving terminal 3. It can be understood that, in FIG. 4, Ant is a connecting point between the duplexer chip and the antenna terminal 1 of the substrate, Rx is a connecting point between the receiving filter and the receiving terminal 3 of the substrate, and Tx is a connecting point between the transmitting filter and the transmitting terminal 2 of the substrate. Further, the receiving filter includes a series resonance arm S5 (a fifth series resonance arm), a series resonance arm S6 (a sixth series resonance arm), and a series resonance arm S7 (a seventh series resonance arm) sequentially connected in series between the antenna terminal 1 and the receiving terminal 3. A DMS filter, which is longitudinally coupled resonator-type surface acoustic wave filter, is connected between the series resonance arm S5 and the series resonance arm S6. One end of the series resonance arm S6 is connected to the series resonance arm S7 and a parallel resonance arm P4 (a fourth parallel resonance arm). A grounding end of the DMS filter is connected to each of a first ground potential 4 and a fifth ground potential 5, and the other end of the parallel resonance arm P4 is connected to the first ground potential 4. Comprehensively considering the design of transmitting power and layout area, as a specific optimal configuration, the series resonance arm S5 includes two SAW-type resonators S5a and S5b connected in series. One end of the resonator S5a is connected to the antenna terminal 1, and the other end of the resonator S5a is connected to one end of the resonator S5b. The other end of the resonator S5b is connected to an input end of the DMS filter. An output end of the DMS filter is connected to one end of the series resonance arm S6. The other end of the series resonance arm S6 is connected to one end of the series resonance arm S7. The other end of the series resonance arm S7 is connected to the receiving terminal 3. In the present embodiment, each of the series resonance arm S6 and the series resonance arm S7 is configured with an SAW resonator. The parallel resonance arm P4 with one end connected between the series resonance arm S6 and the series resonance arm S7 includes two SAW-type resonators, i.e., a resonator P4a and a resonator P4b, and the resonator P4b is connected to a second ground potential 5.

The transmitting filter includes a series resonance arm S1 (a first series resonance arm), a series resonance arm S2 (a second series resonance arm), a series resonance arm S3 (a third series resonance arm), and a series resonance arm S4 (a fourth series resonance arm) sequentially connected in series between the transmitting terminal 2 and the antenna terminal 1. One end of a parallel resonance arm P1 (a first parallel resonance arm) is connected between the series resonance arm S1 and the series resonance arm S2. One end of a parallel resonance arm P2 (a second parallel resonance arm) is connected between the series resonance arm S2 and the series resonance arm S3. One end of a parallel resonance arm P3 (a third parallel resonance arm) is connected between the series resonance arm S3 and the series resonance arm S4. The other ends of the parallel resonance arm P1, the other end of the parallel resonance arm P2, and the other end of the parallel resonance arm P3 are commonly connected to a third ground potential 6. Comprehensively considering the design of transmitting power and layout area, as a specific optimal configuration, the series resonance arm S1 includes three SAW-type resonators, i.e., a resonator S1a, a resonator S1b, and a resonator S1c. The series resonance arm S2 includes three SAW-type resonators, i.e., a resonator S2a, a resonator S2b, and a resonator S2c. The series resonance arm S4 includes three SAW-type resonators, i.e., a resonator S4a, a resonator S4b, and a resonator S4c. The series resonance arm S3 includes two SAW-type resonators, i.e., a resonator S3a and a resonator S3b. The parallel resonance arm P1 includes two SAW-type resonators, i.e., a resonator P1a and a resonator P1b. The parallel resonance arm P2 includes two SAW-type resonators, i.e., a resonator P2a and a resonator P2b. The parallel resonance arm P3 includes two SAW-type resonators, i.e., a resonator P3a and a resonator P3b. One end of the resonator P1b, one end of the resonator P2b, and one end of the resonator P3b are commonly connected to a third ground potential 6.

Further, as a specific optimal configuration, the DMS filter is a 9th-order unbalanced DMS filter. In order to optimize the arrangement structure and improve performance, the ground ends of all resonators in the DMS filter may be commonly connected to the first ground potential 4 and the second ground potential 5.

As a preferred implementation mode, one grounding end of the DMS filter is connected to the first ground potential 4 through a first grounding metal wiring 8, and the other grounding end of the DMS filter is connected to the second ground potential 5 through a second grounding metal wiring 9. The second ground potential 5 is connected to an inductor L1 at a metal layer of a substrate, and the inductance value of the inductor L1 is 0.2 nH. The first ground potential 4 is not connected with an inductor at the metal layer of the substrate. The parallel resonance arm P4 is connected to the first ground potential 4 through a third grounding metal wiring 10. Through the above solution settings, the isolation of the duplexer can be improved.

As a further preference, the parallel resonance arm Pl, the parallel resonance arm P2, and the parallel resonance arm P3 are commonly connected to the third ground potential 6 through grounding metal wirings. The third ground potential 6 is connected to an inductor L2 at the metal layer of the substrate, and the inductance value of the inductor L2 is 0.1 nH. As shown in FIG. 4, as a specific optimal configuration, the parallel resonance arm P1 and the parallel resonance arm P2 are connected to the third ground potential 6 through a fourth grounding metal wiring 11. The parallel resonance arm P3 is connected to the third ground potential 6 through a fifth grounding metal wiring 12.

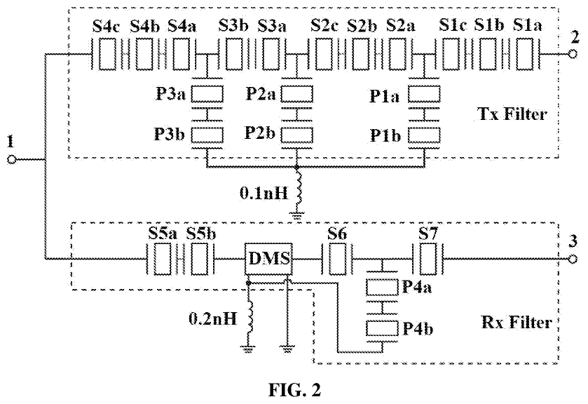

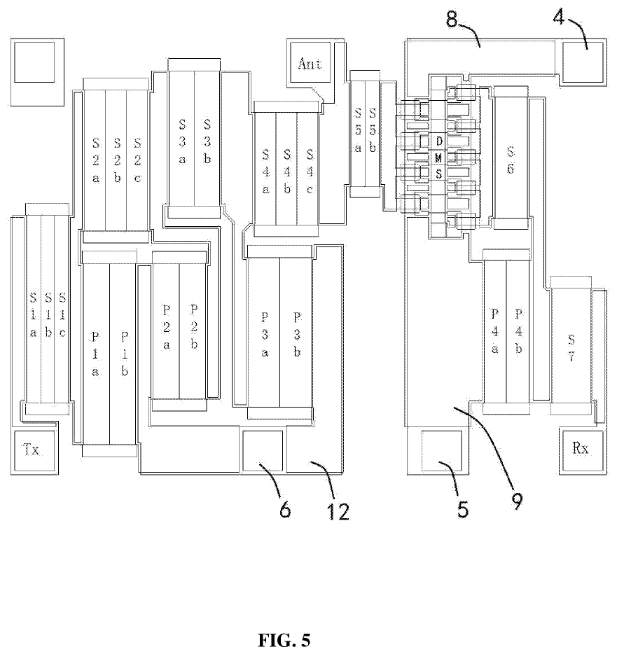

FIG. 2 illustrates a circuit diagram of a duplexer of provided comparative example 1. FIG. 5 illustrates an arrangement diagram of the transmitting filter and the receiving filter on the surface of the piezoelectric substrate of comparative example 1. The main difference between comparative example 1 and the above embodiments is that comparative example 1 changes the arrangement position of the parallel resonance arm P4 on the basis of the embodiment, and the parallel resonance arm P4 is connected to the second ground potential 5 through the grounding metal wiring.

As a preferred implementation mode, the distance between the grounding metal wiring of the DMS filter in the receiving filter and the grounding metal wiring of the parallel resonance arm in the transmitting filter should be spaced apart as far as possible. In order to ensure the isolation, the distance between the grounding metal wiring of the DMS filter and the grounding metal wiring of the parallel resonance arm in the transmitting filter is greater than 100 μm, and the distance between the grounding metal wiring of the DMS filter and a signal metal wiring of the receiving filter is within the range of 30 to 50 μm. Therefore, the isolation of the duplexer can be further improved. More specifically, taking a specific structure shown in FIG. 4 as an example, the distance between the grounding metal wiring (including the first grounding metal wiring 8 and the second grounding metal wiring 9) of the DMS filter and the grounding metal wiring (the fifth grounding metal wiring 12) of the parallel resonance arm P3 in the transmitting filter is greater than 100 μm, and the distance between the grounding metal wiring of the DMS filter and the signal metal wiring (including a first signal metal wiring 13 and a second signal metal wiring 14) of the receiving filter is within the range of 30 to 50 μm. It can be understood that the first signal metal wiring 13 serves as a signal connecting line between the DMS filter and the series resonance arm S6, and the second signal metal wiring 14 serves as a signal connecting line for connecting the series resonance arm S7 and the parallel resonance arm P4 via the series resonance arm S6.

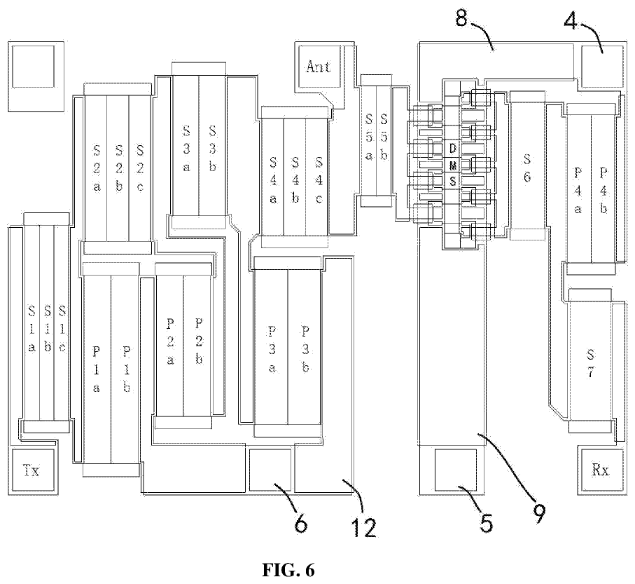

FIG. 6 illustrates an arrangement diagram of the transmitting filter and the receiving filter on the surface of the piezoelectric substrate of provided comparative example 2. The difference between comparative example 2 and the above embodiment is that: in comparative example 2, the distance between the grounding metal wiring of the DMS filter and the grounding metal wiring of the parallel resonance arm in the transmitting filter, and the distance between the grounding metal wiring of the DMS filter and the signal metal wiring in the receiving filter are set to be different from those in the above embodiments. In particular, in comparative example 2, the distance between the grounding metal wiring connecting the DMS filter to the second ground potential 5 and the grounding metal wiring of the parallel resonance arm in the transmitting filter is obviously less than the corresponding distance in the above embodiment.

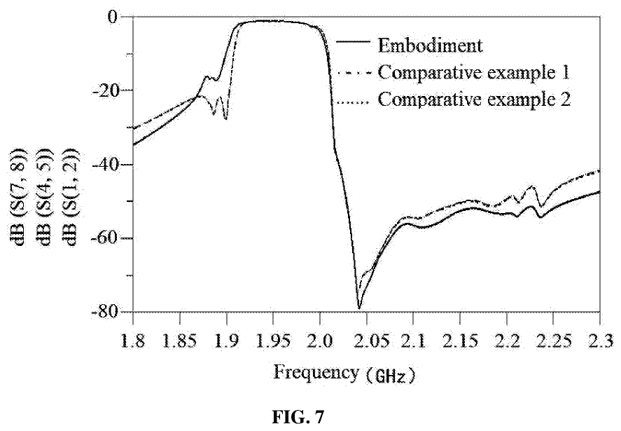

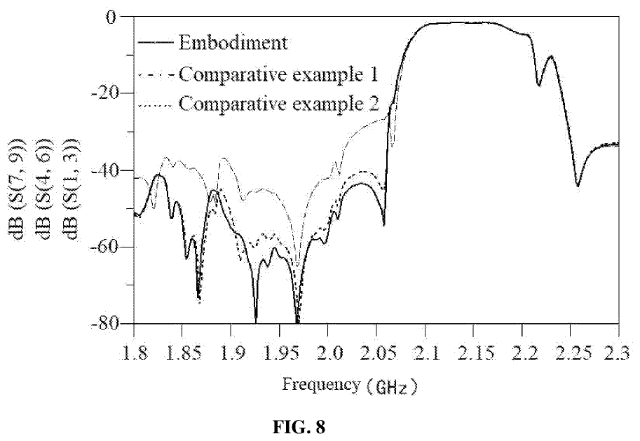

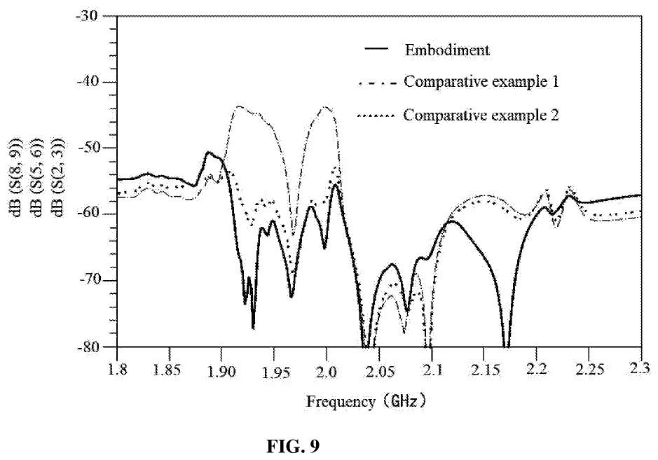

In order to verify the technical effect of the provided embodiment, the duplexer of the embodiment, and the duplexers of comparative example 1 and comparative example 2 are subjected to comparative test. FIG. 7 illustrates transmission curves of the transmitting filters of the embodiment of the present disclosure, comparative example 1, and comparative example 2. In FIG. 7, the transmission curves of comparative example 1 and comparative example 2 coincide. FIG. 8 illustrates transmission curves of the receiving filters of the embodiment of the present disclosure, comparative example 1, and comparative example 2. FIG. 9 illustrates isolation curves of the embodiment of the present disclosure, comparative example 1, and comparative example 2. It can be seen from the drawings that, in the embodiment of the present disclosure, the isolation performance of the SAW duplexer is obviously improved and is superior to that of the comparative examples by adjusting the positions of the parallel resonance arms of the receiving filter and optimizing the distance between the grounding metal wiring of the DMS filter in the receiving filter and other grounding metal wirings, and the distance between the grounding metal wiring of the DMS filter in the receiving filter and the signal metal wiring.

As a preferred implementation mode, the resonance frequencies fₛ of the series resonance arm S5 and the series resonance arm S6 are within a pass band range of the receiving filter. An anti-resonance frequency fₐ of the series resonance arm S7 is within the pass band range of the transmitting filter. Therefore, the isolation of the duplexer can be further improved.

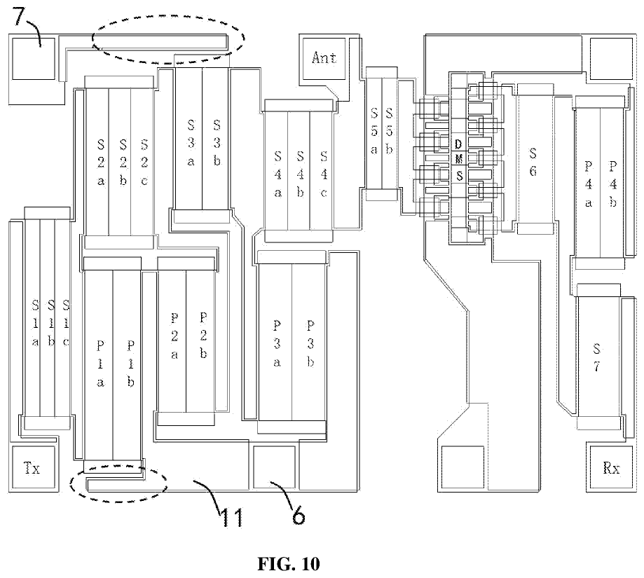

The present disclosure further provides a high-isolation and anti-glue-invasion SAW duplexer, including the above duplexer. In the duplexer, the grounding metal wiring for connecting the ground potential has an extension section, which is arranged to surround the series resonance arms and the parallel resonance arms, so as to fill blank positions between the resonance arms and the edge of the package. As shown in FIG. 10, as a specific implementation mode, the grounding metal wiring connected to the fourth ground potential 7 and the grounding metal wiring connected to the third ground potential 6 are extended (a dotted box in FIG. 10 indicates an extension part). Specifically, the grounding metal wiring connected to the fourth ground potential 7 is extended to surround the series resonance arm S3, and the grounding metal wiring connected to the third ground potential 6 is extended to surround the parallel resonance arm P2, so as to prevent glue from eroding the series resonance arm S3 and the parallel resonance arm P2. Further, the arrangement of the grounding metal wirings of other sections can also be combined and arranged to surround the series resonance arms and the parallel resonance arms, to fill the blank positions between the resonance arms and the edge of the package, which can effectively avoid the situation that sealing glue is in contact with the resonators when the duplexer is packaged, resulting in the deterioration of the resonator performance It is worth noting that the layout of the transmitting filter is often close to the edge of the package according to the filtering performance and the power of the existing duplexer. In order to prevent the glue from entering the SAW device to erode an SAW device during packaging, the common practice is that, according to the layout position of the SAW device, the distance between an edge interdigital structure of the SAW device and an outer frame of the package should be greater than 30 pm, which limits the overall layout and design flexibility of the SAW device, and the practicability of prevent glue from entering the SAW device cannot be guaranteed. In the present embodiment, the problem is well solved from the perspective of the design of the SAW duplexer, which achieves a good application effect without increasing the manufacturing cost.

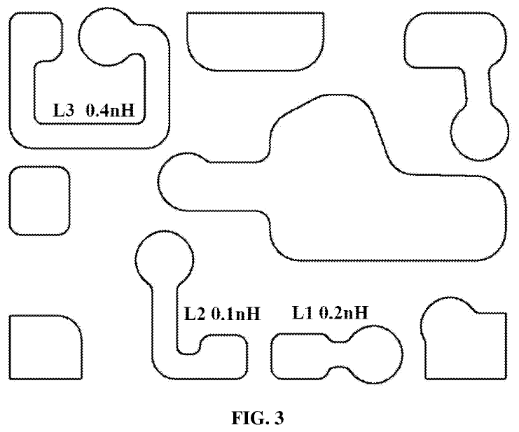

FIG. 3 illustrates a schematic top view of a structure of each metal layer of a substrate according to the embodiment of the present disclosure. The second ground potential 5 is connected to an inductor L1 at the metal layer of the substrate, the third ground potential 6 is connected to an inductor L2 at the metal layer of the substrate, and the fourth ground potential 7 is connected to an inductor L3 at the metal layer of the substrate.

Various embodiments in the present specification are described in a progressive manner. Each embodiment focuses on differences from other embodiments, and the same and similar parts of various embodiments may be referred to one another.

In this specification, specific examples are used to describe the principle and implementation manners of the present disclosure. The description of the embodiments above is merely intended to help understand the method and core idea of the present disclosure. In addition, those skilled in the art may make modifications based on the idea of the present disclosure with respect to the specific implementation manners and the application scope. In conclusion, the contents of the present specification shall not be construed as a limitation to the present disclosure.

What is claimed is:

1. A high-isolation Surface Acoustic Wave (SAW) duplexer, comprising an antenna terminal, a transmitting terminal, a receiving terminal, a substrate, and a duplexer chip arranged on the substrate, the duplexer chip comprising a piezoelectric substrate, and a transmitting filter and a receiving filter constructed on a surface of the piezoelectric substrate, the transmitting filter being connected between the antenna terminal and the transmitting terminal, and the receiving filter being connected between the antenna terminal and the receiving terminal, wherein:
the receiving filter comprises a series resonance arm S5, a series resonance arm S6, and a series resonance arm S7 sequentially connected in series between the antenna terminal and the receiving terminal;
a Double Mode Structure (DMS) filter is connected between the series resonance arm S5 and one end of the series resonance arm S6;
an other end of the series resonance arm S6 is connected to the series resonance arm S7 and one end of a parallel resonance arm P4;
grounding ends of the DMS filter are respectively connected to a first ground potential and a second ground potential;
an other end of the parallel resonance arm P4 is connected to the first ground potential or the second ground potential;
the transmitting filter comprises a parallel resonance arm P1, a parallel resonance arm P2, and a parallel resonance arm P3;
the transmitting filter further comprises a series resonance arm S1, a series resonance arm S2, a series resonance arm S3, and a series resonl5ance arm S4 sequentially connected in series between the transmitting terminal and the antenna terminal;
one end of the parallel resonance arm P1 is connected between the series resonance arm S1 and the series resonance arm S2;
one end of the parallel resonance arm P2 is connected between the series resonance arm S2 and the series resonance arm S3;
one end of the parallel resonance arm P3 is connected between the series resonance arm S3 and the series resonance arm S4; and
an other end of the parallel resonance arm P1, an other end of the parallel resonance arm P2, and an other end of the parallel resonance arm P3 are connected to a third ground potential.

2. The high-isolation SAW duplexer of claim 1, wherein:
a first grounding end of the DMS filter is connected to the first ground potential through a first grounding metal wiring;
a second grounding end of the DMS filter is connected to the second ground potential through a second grounding metal wiring;
the second ground potential is connected with an inductor L1 at a metal layer of the substrate, and an inductance value of the inductor L1 is 0.2 nH;
the first ground potential is not connected with an inductor at the metal layer of the substrate; and
the parallel resonance arm P4 is connected to the first ground potential through a third grounding metal wiring.

3. The high-isolation SAW duplexer of claim 2, wherein:
the other end of the parallel resonance arm Pl, the other end of the parallel resonance arm P2, and the other end of the parallel resonance arm P3 are commonly connected to the third ground potential through grounding metal wirings;
the third ground potential is connected to an inductor L2 at the metal layer of the substrate, and an inductance value of the inductor L2 is 0.1 nH;
a distance between the second grounding metal wiring of the DMS filter in the receiving filter and the grounding metal wiring of the parallel resonance arm in the transmitting filter is greater than 100 μm; and
a distance between the second grounding metal wiring of the DMS filter and a signal metal wiring in the receiving filter is within a range of 30 to 50 μm.

4. The high-isolation SAW duplexer of claim 1, wherein:
each of the series resonance arm S1, the series resonance arm S2, and the series resonance arm S4 comprises three SAW resonators; each of the series resonance arm S3, the parallel resonance arm P1, the parallel resonance arm P2, and the parallel resonance arm P3 comprises two SAW resonators; and
each of the series resonance arm S5 and the parallel resonance arm P4 comprises two SAW resonators.

5. The high-isolation SAW duplexer of claim 4, wherein resonance frequencies fₛ of the series resonance arm S5 and the series resonance arm S6 are within a pass band range of the receiving filter; and an anti-resonance frequency fₐ of the series resonance arm S7 is within a pass band range of the transmitting filter.

6. A high-isolation SAW duplexer, comprising an antenna terminal, a transmitting terminal, a receiving terminal, and a duplexer chip, wherein:
the duplexer chip comprises a transmitting filter and a receiving filter;
one end of the transmitting filter is connected to the antenna terminal;
an other end of the transmitting filter is connected to the transmitting terminal;
one end of the receiving filter is connected to the antenna terminal; and
an other end of the receiving filter is connected to the receiving terminal.

7. The high-isolation SAW duplexer of claim 6, wherein:
the duplexer chip further includes a piezoelectric substrate; and
the transmitting filter and the receiving filter are arranged on the piezoelectric substrate.

8. The high-isolation SAW duplexer of claim 6, wherein:
the transmitting filter comprises: a first series resonance arm, a second series resonance arm, a third series resonance arm, a fourth series resonance arm, a first parallel resonance arm, a second parallel resonance arm, and a third parallel resonance arm;
one end of the first series resonance arm is connected to the transmitting terminal;
an other end of the first series resonance arm is connected to one end of the second series resonance arm;
an other end of the second series resonance arm is connected to one end of the third series resonance arm;
an other end of the third series resonance arm is connected to one end of the fourth series resonance arm;
an other end of the fourth series resonance arm is connected to the antenna terminal;
one end of the first parallel resonance arm is connected to a connection path between the first series resonance arm and the second series resonance arm;
one end of the second parallel resonance arm is connected to a connection path between the second series resonance arm and the third series resonance arm;
one end of the third parallel resonance arm is connected to a connection path between the third series resonance arm and the fourth series resonance arm; and
an other end of the first parallel resonance arm, an other end of the second parallel resonance arm, and an other end of the third parallel resonance arm are grounded.

9. The high-isolation SAW duplexer of claim 6, wherein:
the receiving filter comprises a fifth series resonance arm, a sixth series resonance arm, a seventh series resonance arm, a fourth parallel resonance arm, and a DMS filter;
one end of the fifth series resonance arm is connected to the antenna terminal;
an other end of the fifth series resonance arm is connected to one end of the DMS filter through a signal metal wiring;
an other end of the DMS filter is connected to one end of the sixth series resonance arm through a signal metal wiring;
an other end of the sixth series resonance arm is connected to one end of the seventh resonance arm;
an other end of the seventh series resonance arm is connected to the receiving terminal;
a first grounding end of the DMS filter is connected to a first ground potential through a grounding metal wiring;
a second grounding end of the DMS filter is connected to a second ground potential through a grounding metal wiring;
one end of the fourth parallel resonance arm is connected to a connection path between the sixth series resonance arm and the seventh series resonance arm; and
an other end of the fourth parallel resonance arm is connected to a connection path between the first grounding end of the DMS filter and the first ground potential.

10. A high-isolation and anti-glue-invasion SAW duplexer comprising the high-isolation SAW duplexer of claim 1, wherein, in the high-isolation SAW duplexer, the grounding metal wiring for connecting the ground potential includes an extension section to surround the series resonance arms and the parallel resonance arms.

11. A high-isolation and anti-glue-invasion SAW duplexer comprising the high-isolation SAW duplexer of claim 2, wherein, in the high-isolation SAW duplexer, the grounding metal wiring for connecting the ground potential includes an extension section to surround the series resonance arms and the parallel resonance arms.

12. A high-isolation and anti-glue-invasion SAW duplexer comprising the high-isolation SAW duplexer of claim 3, wherein, in the high-isolation SAW duplexer, the grounding metal wiring for connecting the ground potential includes an extension section to surround the series resonance arms and the parallel resonance arms.

13. A high-isolation and anti-glue-invasion SAW duplexer comprising the high-isolation SAW duplexer of claim 4, wherein, in the high-isolation SAW duplexer, the grounding metal wiring for connecting the ground potential includes an extension section to surround the series resonance arms and the parallel resonance arms.

14. A high-isolation and anti-glue-invasion SAW duplexer comprising the high-isolation SAW duplexer of claim 5, wherein, in the high-isolation SAW duplexer, the grounding metal wiring for connecting the ground potential includes an extension section to surround the series resonance arms and the parallel resonance arms.

15. A high-isolation and anti-glue-invasion SAW duplexer comprising the high-isolation SAW duplexer of claim 6, wherein, in the high-isolation SAW duplexer, the grounding metal wiring for connecting the ground potential includes an extension section to surround the series resonance arms and the parallel resonance arms.

16. A high-isolation and anti-glue-invasion SAW duplexer comprising the high-isolation SAW duplexer of claim 7, wherein, in the high-isolation SAW duplexer, the grounding metal wiring for connecting the ground potential includes an extension section to surround the series resonance arms and the parallel resonance arms.

17. A high-isolation and anti-glue-invasion SAW duplexer comprising the high-isolation SAW duplexer of claim 8, wherein, in the high-isolation SAW duplexer, the grounding metal wiring for connecting the ground potential includes an extension section to surround the series resonance arms and the parallel resonance arms.

18. A high-isolation and anti-glue-invasion SAW duplexer comprising the high-isolation SAW duplexer of claim 9, wherein, in the high-isolation SAW duplexer, the grounding metal wiring for connecting the ground potential includes an extension section to surround the series resonance arms and the parallel resonance arms.
